(19) United States
(12) Patent Application Publication
(10) Pub. No.: US 2016/0201218 A1
(43) Pub. Date: Jul. 14, 2016

(54) METHOD FOR FABRICATING SINGLE-CRYSTALLINE NIOBIUM OXYNITRIDE FILM AND METHOD FOR GENERATING HYDROGEN USING SINGLE-CRYSTALLINE NIOBIUM OXYNITRIDE FILM

(71) Applicant: Panasonic Intellectual Property Management Co., Ltd., Osaka (JP)

(72) Inventors: RYOSUKE KIKUCHI, Osaka (JP); TAKAIKI NOMURA, Osaka (JP); KAZUHITO HATO, Osaka (JP); SATORU TAMURA, Osaka (JP); TAKAHIRO KURABUCHI, Osaka (JP)

(21) Appl. No.: 15/075,226

(22) Filed: Mar. 21, 2016

Related U.S. Application Data
(63) Continuation of application No. PCT/JP2015/005071, filed on Oct. 6, 2015.

(30) Foreign Application Priority Data
Nov. 14, 2014 (JP) 2014-231832

(51) Int. Cl. C30B 25/06; C25B 1/04; C25B 11/04; C30B 29/38; C23C 14/06; C23C 14/00; C30B 29/16; C25B 1/00; H01G 9/20

(52) U.S. Cl. CPC C30B 25/06; C25B 1/003; C25B 1/04; C25B 11/0452; H01G 9/20; C23C 14/0676; C23C 14/0036; C30B 29/16; C30B 29/38

(57) ABSTRACT

The present invention provides a method for fabricating a single-crystalline niobium oxynitride film suitable for a hydrogen generation device. The present invention provides a method for fabricating a single-crystalline niobium oxynitride film formed of a niobium oxynitride represented by the chemical formula NbON; the method comprising: (a) epitaxially growing the single-crystalline niobium oxynitride film on one substrate selected from the group consisting of a yttria-stabilized zirconia substrate, a titanium oxide substrate, and a yttrium-aluminum complex oxide substrate.

This is a continuation of International Application No. PCT/JP2015/005071, with an international filing date of Oct. 6, 2015, which claims priority of Japanese Patent Application No. 2014-231832, filed on Nov. 14, 2014, the contents of which are hereby incorporated by reference.

### BACKGROUND

1. Technical Field

The present invention relates to a method for fabricating a single-crystalline niobium oxynitride film. In particular, the present invention relates to a method for fabricating a single-crystalline niobium oxynitride film suitable for a semiconductor photoelectrode used to generate hydrogen.

2. Description of the Related Art

Nomura et al. (United States Patent Pre-Grant Publication No. 2013/0192984) discloses a NbON film and a fabrication method thereof, a hydrogen generation device, and an energy system comprising the same. FIG. 16 shows a schematic view of a hydrogen generation device 600 disclosed in Nomura et al. This hydrogen generation device 600 comprises a semiconductor photoelectrode 620 including an electric conductor 621; a NbON film 622 disposed on the electric conductor 621; a counter electrode 630 electrically connected to the electric conductor 621; an electrolyte solution 640 which is in contact with the surfaces of the NbON film 622 and the counter electrode 630 and which contains water; and a container 610 which contains the semiconductor photoelectrode 620, the counter electrode 630, and the electrolyte solution 640. Hydrogen is generated by irradiating the NbON film 622 with light. According to Nomura et al., it is desirable that the NbON film 622 is single-phase.

Nesper et al. (United States Patent Pre-Grant Publication No. 2011/0305949) discloses in the paragraph 0006 thereof that, in Von M. Weishaupt et. al., “Darstellung der Oxidnitride VON, NbON, und TaON. Die Kristallstruktur von NbON und TaON”, J. Z. anorg. allg. Chem. 429, 261-269 (1977), a single-crystal NbNO was synthesized by reacting NbOCl₃ with an excess amount of NH₄Cl under a temperature of 900-1000 degrees Celsius and that the synthesized material was used to identify the crystal structure thereof.

The present inventors read Von M. Weishaupt et. al. Von M. Weishaupt et. al. discloses that crystals of TaON and NbON were synthesized. Von M. Weishaupt et. al. discloses that single-crystalline TaON was synthesized. However, Von M. Weishaupt et. al. fails to disclose that single-crystalline NbON was synthesized. In other words, Von M. Weishaupt et. al. discloses that NbON was synthesized; however, Von M. Weishaupt et. al. fails to disclose that the synthesized NbON was single-crystalline. The present inventors are afraid that Nesper et al. fail to read Von M. Weishaupt et. al. properly. Von M. Weishaupt et. al. is written in German. Note that the German term “Einkristall” means “single-crystalline”.

### SUMMARY

The present invention provides a method for fabricating a single-crystalline niobium oxynitride film formed of a niobium oxynitride represented by the chemical formula NbON; the method comprising:

(a) epitaxially growing the single-crystalline niobium oxynitride film on one substrate selected from the group consisting of a yttria-stabilized zirconia substrate, a titanium oxide substrate, and a yttrium-aluminum complex oxide substrate.

The present invention provides a method for fabricating a single-crystalline niobium oxynitride film suitable for a hydrogen generation device.

### BRIEF DESCRIPTION OF DRAWINGS

FIG. 1 shows a cross-sectional view of a semiconductor photoelectrode 100 according to an embodiment.

FIG. 2 shows a cross-sectional view of a hydrogen generation device according to the embodiment.

FIG. 3A shows a cross-sectional view of the semiconductor photoelectrode 100 according to a first variation.

FIG. 3B shows a cross-sectional view of the semiconductor photoelectrode 100 according to a second variation.

FIG. 4 shows a graph of a 2θ-ω scan result in an inventive example 1.

FIG. 5 shows a drawing of a pole measurement result of a single-crystalline NbON film 120 in the inventive example 1.

FIG. 6 shows a drawing of a cross-sectional SEM image of the semiconductor photoelectrode 100 according to the inventive example 1.

FIG. 7 shows a graph of a result of composition analysis of the semiconductor photoelectrode 100 along a depth direction thereof by a Rutherford back scattering analysis method in the inventive example 1.

FIG. 8 shows a graph of a 2θ-ω scan result in an inventive example 2.

FIG. 9 shows a graph of a 2θ-ω scan result in an inventive example 3.

FIG. 10 shows a graph of a result of a grazing-incidence X-ray diffraction measurement analysis in a comparative example 1a.

FIG. 11 shows a drawing of a cross-sectional SEM image of the semiconductor photoelectrode 100 according to the comparative example 1a.

FIG. 12 shows a graph of a result of a grazing-incidence X-ray diffraction measurement analysis in a comparative example 1b.

FIG. 13 shows a drawing of a cross-sectional SEM image of the semiconductor photoelectrode 100 according to the comparative example 1b.

FIG. 14 shows a graph of a result of a grazing-incidence X-ray diffraction measurement analysis in a comparative example 2.

FIG. 15 shows a graph of a result of composition analysis of the semiconductor photoelectrode 100 along a depth direction thereof by a Rutherford back scattering analysis method in the comparative example 2.

FIG. 16 shows a cross-sectional view of the hydrogen generation device disclosed in Nomura et al.

### DESCRIPTION OF EMBODIMENT

Hereinafter, the embodiment of the present invention will be described with reference to the drawings.

### Embodiment

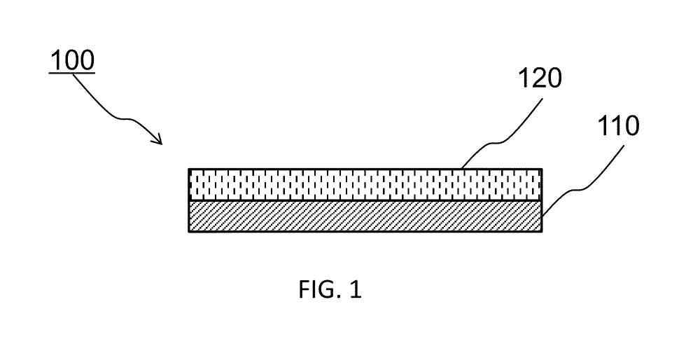

FIG. 1 shows a cross-sectional view of a semiconductor photoelectrode 100 according to the embodiment. The semiconductor photoelectrode 100 according to the embodiment comprises a substrate 110 and a single-crystalline niobium oxynitride film (hereinafter, referred to as “single-crystalline NbON film”) 120 formed on the surface of the substrate 110. NbON is an n-type semiconductor. The single-crystalline NbON film 120 is formed of a niobium oxynitride represented by the chemical formula NbON. It is desirable that the single-crystalline NbON film 120 is oriented in a certain direction such as a [100] direction or a [001] direction. In other words, it is desirable that the single-crystalline NbON film 120 has an orientation plane of a (100) plane or a (001) plane. Note that the single-crystalline NbON film may have a slight offset angle. The term “offset angle” means an angle formed between the surface of the film and the orientation plane.

(Method for Fabricating the Single-Crystalline NbON Film)

The single-crystalline NbON film 120 is epitaxially grown on the substrate 110. The substrate 110 is selected from the group consisting of a yttria-stabilized zirconia (hereinafter, referred to as “YSZ”) substrate, a titanium oxide substrate, and a yttrium-aluminum complex oxide substrate, as is clear from examples which will be described later. Each of surfaces of these substrates has crystallinity.

It is desirable that the substrate 110 is also oriented in a certain direction. In particular, it is desirable that the substrate 110 is selected from the group consisting of a YSZ substrate having a (100) orientation plane, a titanium oxide substrate having a (101) orientation plane, and a yttrium-aluminum complex oxide substrate having a (001) orientation plane. Needless to say, titanium oxide is represented by the chemical formula TiO₂. The yttrium-aluminum complex oxide is represented by the chemical formula YAlO₃.

An example of the YSZ substrate is a substrate formed of YSZ having a (100) orientation or a substrate having a layer formed of YSZ having a (100) orientation on the surface thereof. As just described, the YSZ substrate includes a substrate obtained by forming a layer formed of YSZ having a (100) orientation on a surface of a substrate. The same matter is applied to the titanium oxide substrate and the yttrium-aluminum complex oxide substrate.

An example of the epitaxial growth method is a sputtering method, a molecular beam epitaxial method, a pulse laser deposition method, or a metalorganic chemical vapor deposition method.

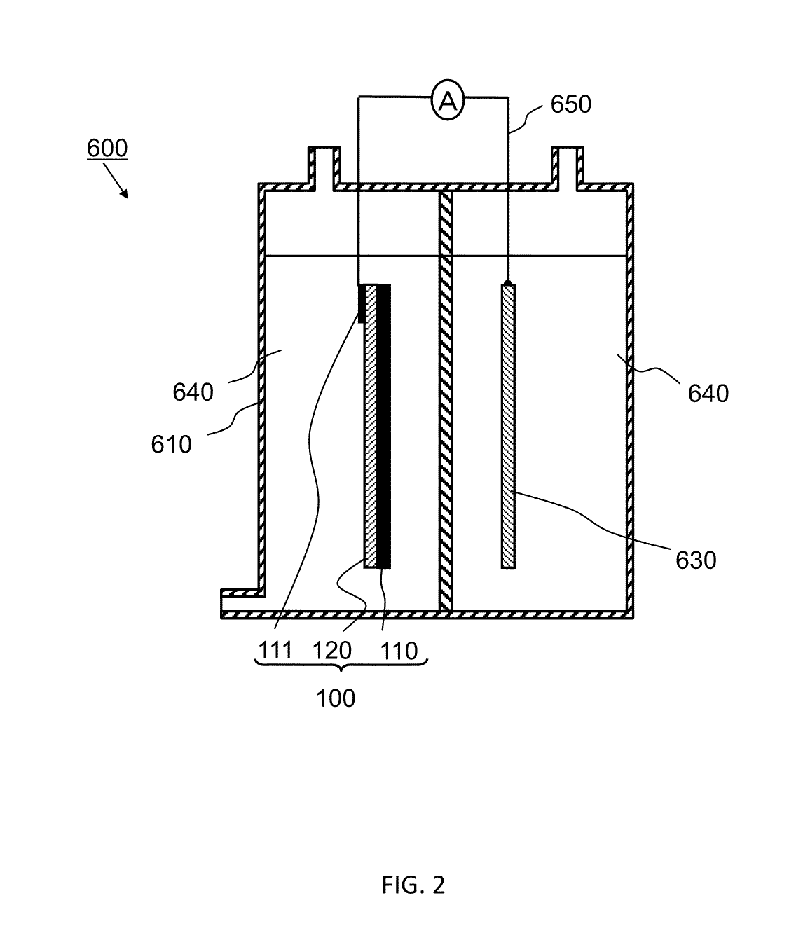

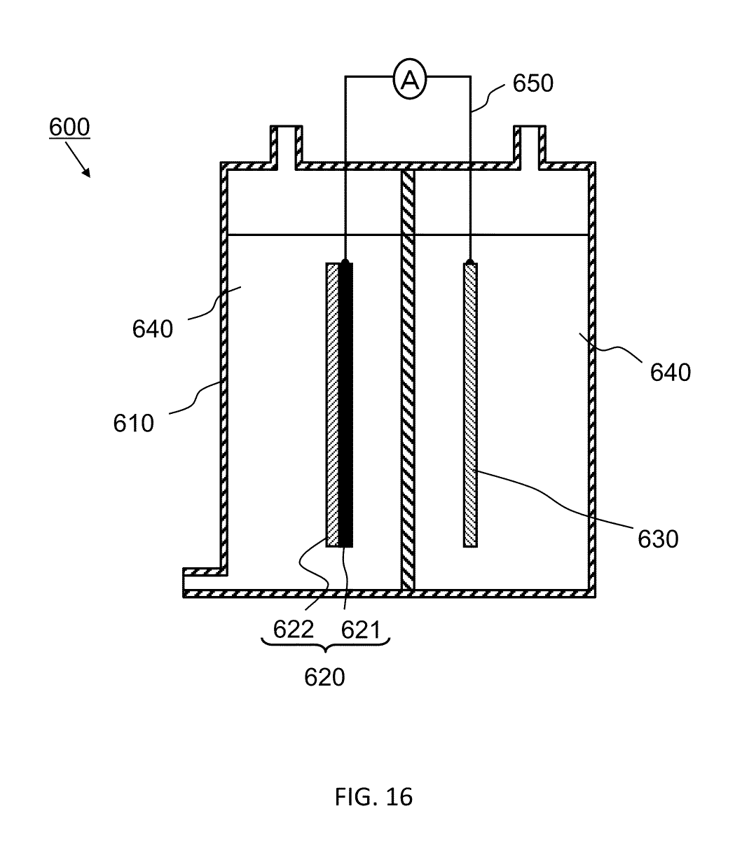

FIG. 2 shows a cross-sectional view of a hydrogen generation device using the semiconductor photoelectrode 100 comprising the single-crystalline niobium oxynitride film 120. Similarly to the case of FIG. 16, the hydrogen generation device shown in FIG. 2 comprises the semiconductor photoelectrode 100, a counter electrode 630, a liquid 640, and a container 610. As described above, the semiconductor photoelectrode 100 comprises the substrate 110 and the single-crystalline NbON film 120. It is desirable that the substrate 110 is electrically conductive. An ohmic electrode 111 is formed on the single-crystalline NbON film 120, and the counter electrode 630 is electrically connected to the ohmic electrode 111 through a conducting wire 650. For more detail, see Nomura et al., the entire contents of which are incorporated herein by reference.

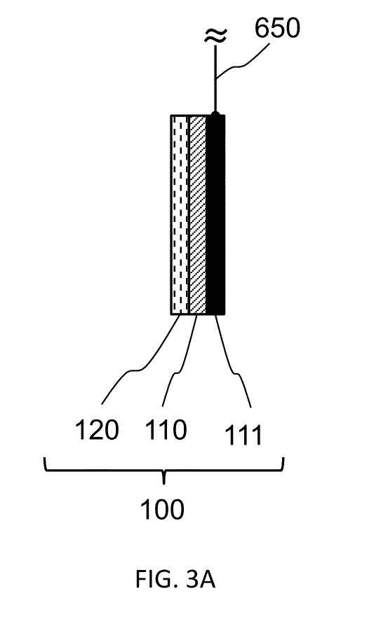

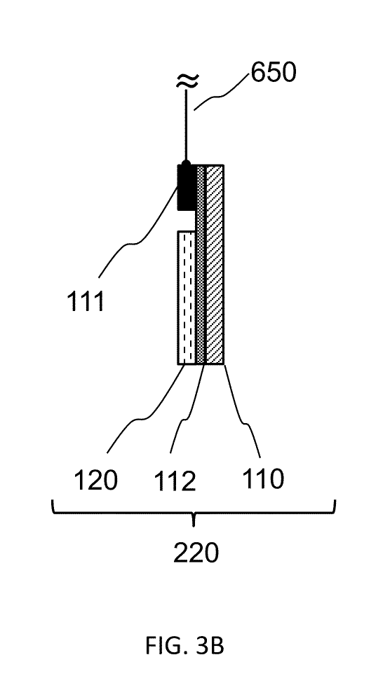

FIG. 3A shows a cross-sectional view of the semiconductor photoelectrode 100 according to a first variation. In the first variation, a titanium oxide substrate 110 is used. After a titanium oxide substrate is doped with niobium, electrical conductivity is imparted to the titanium oxide substrate. For this reason, after the titanium oxide substrate 110 having the single-crystalline NbON film 120 on the front surface thereof is doped with niobium from the back surface thereof, electrical conductivity is imparted to the titanium oxide substrate 110. Then, as shown in FIG. 3A, an ohmic electrode 111 is formed on the back surface of the titanium oxide substrate 110 having electrical conductivity. The ohmic electrode 111 is electrically connected to the conducting wire 650.

FIG. 3B shows a cross-sectional view of the semiconductor photoelectrode 100 according to a second variation. In the second variation, a YSZ substrate 110 is used. After a YSZ substrate is annealed in a vacuum, the surface of the YSZ substrate is reduced. On the other hand, the crystallinity of the surface of the YSZ substrate is maintained. As a result, electrical conductivity is imparted to the surface of the YSZ substrate. In this way, a conductive film 112 is formed on the YSZ substrate 110. Then, the single-crystalline NbON film 120 is epitaxially grown on the conductive film 112. Furthermore, the ohmic electrode 111 is formed on the conductive film 112. In this way, the semiconductor photoelectrode 100 according to the second variation is provided. The ohmic electrode 111 is electrically connected to the conducting wire 650.

It is desirable that the counter electrode 630 is formed of a material having a small overvoltage. In particular, an example of the material of the counter electrode 630 is platinum, gold, silver, nickel, ruthenium oxide represented by the chemical formula RuO₂, or iridium oxide represented by the chemical formula IrO₂.

The liquid 640 is water or an electrolyte aqueous solution. The electrolyte aqueous solution is acidic or alkaline. An example of the electrolyte aqueous solution is a sulfuric acid solution, a sodium sulfate solution, a sodium carbonate solution, a phosphate buffer solution, or a borate buffer solution. The liquid 640 may be constantly stored in the container 610 or may be supplied only in use.

The container 610 contains the semiconductor photoelectrode 100, the counter electrode 630, and the liquid 640. It is desirable that the container 610 is transparent. In particular, it is desirable that at least a part of the container 610 is transparent so that light can travel from the outside of the container 610 to the inside of the container 610.

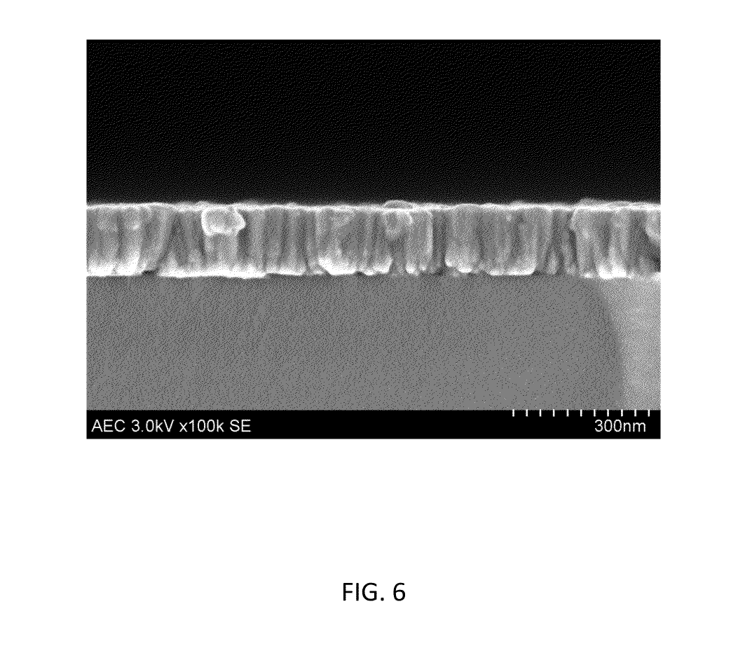

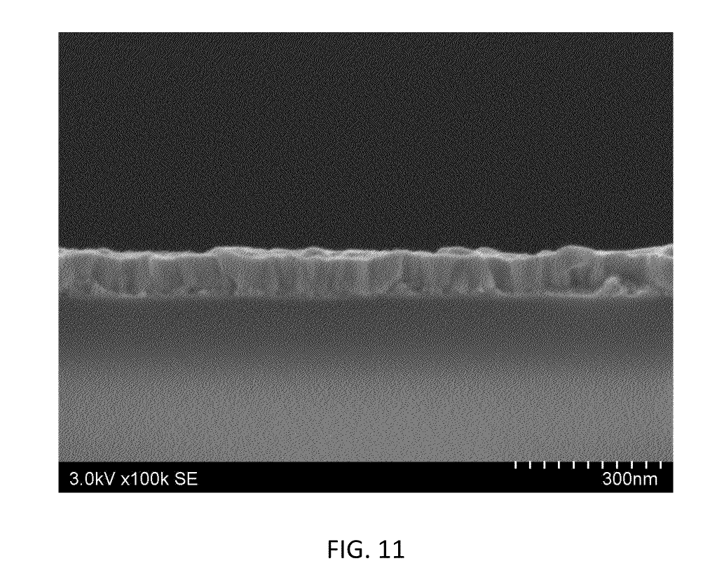

When the single-crystalline NbON film 120 is irradiated with light, oxygen is generated on the single-crystalline NbON film 120. Light such as sunlight travels through the container 610 and reaches the single-crystalline NbON film 120. Electrons and holes are generated respectively in the conduction band and valence band of the part of the single-crystalline NbON film 120 in which the light has been absorbed. Since the single-crystalline NbON film 120 is an n-type semiconductor, the holes migrate to the surface of the single-crystalline NbON film 120. The single-crystalline NbON film 120 has no grain boundary across the migration direction of the holes (namely, the normal direction of the substrate 110). For this reason, the holes generated in the part of the single-crystalline NbON film 120 in which the light has been absorbed migrate to the surface of the single-crystalline NbON film 120 without being trapped by the grain boundary. As understood from FIG. 6 and FIG. 11 which will be described later, a plurality of single-crystalline films may be formed on the substrate 110. In this case, a grain boundary may be formed between two adjacent single-crystalline films. However, such a grain boundary does not prevent the holes from migrating.

Water is split on the surface of the single-crystalline NbON film 120 as shown in the following reaction formula (1) to generate oxygen. On the other hand, electrons migrate from the single-crystalline NbON film 120 to the counter electrode 630 through the conducting wire 650. Hydrogen is generated as shown in the following reaction formula (2) on the surface of the counter electrode 630.

4h⁺+2H₂O→O₂↑+4H⁺ (1)

(h⁺ represents a hole)

4e⁻+4H⁺→2H₂↑ (2)

Since the semiconductor photoelectrode 100 according to the embodiment comprises the substrate 110 on which the single-crystalline niobium oxynitride film 120 has been formed, a hydrogen generation device comprising the semiconductor photoelectrode 100 according to the embodiment has higher hydrogen generation efficiency than a conventional hydrogen generation device comprising an amorphous or poly-crystalline niobium oxynitride film.

### Examples

Hereinafter, the present invention will be described in more detail with reference to the following examples.

### Inventive Example 1

In the inventive example 1, the semiconductor photoelectrode 100 shown in FIG. 1 was fabricated. First, a YSZ substrate 110 having a (100) plane orientation (available from Shinkosha Co., Ltd.) was prepared. While the YSZ substrate 110 was heated to 650 degrees Celsius, a single-crystalline NbON film 120 having a thickness of 150 nanometers was formed on the YSZ substrate 110 by a reactive sputtering method under a mixed atmosphere of oxygen and nitrogen (O₂:N₂=1:20, volume ratio). The sputtering target was formed of niobium nitride represented by the chemical formula NbN.

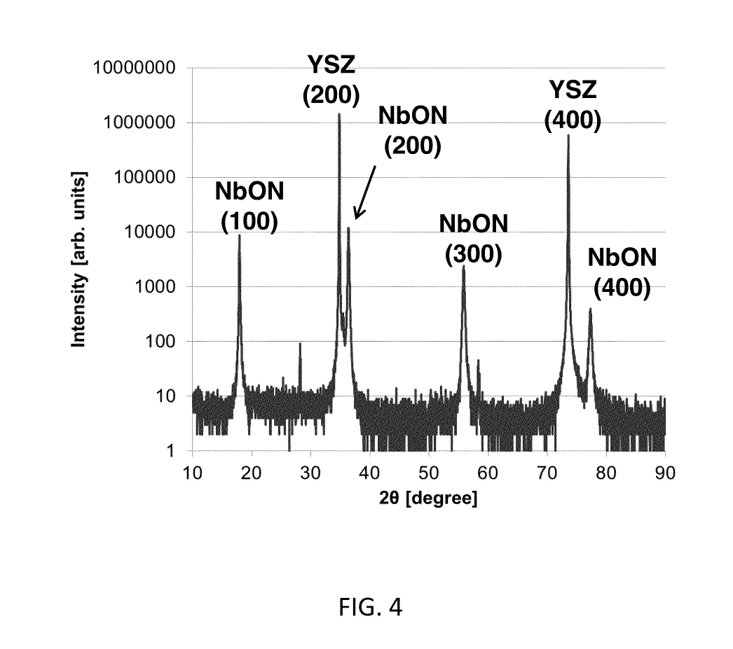

The thus-formed single-crystalline NbON film 120 was subjected to the X-ray diffraction measurement analysis according to a 2θ-ω scan method. FIG. 4 shows a result of the 2θ-ω scan measurement in the inventive example 1. As shown in FIG. 4, observed was six peaks of a (200) plane derived from YSZ, a (400) plane derived from YSZ, a (100) plane derived from NbON, a (200) plane derived from NbON, a (300) plane derived from NbON, and a (400) plane derived from NbON. As just described, except for two peaks derived from the YSZ substrate, only the peaks of (h00) planes derived from NbON were observed. In this way, a single-crystalline NbON film 120 having a (100) plane orientation was epitaxially grown on the YSZ substrate 110 having a (100) plane orientation.

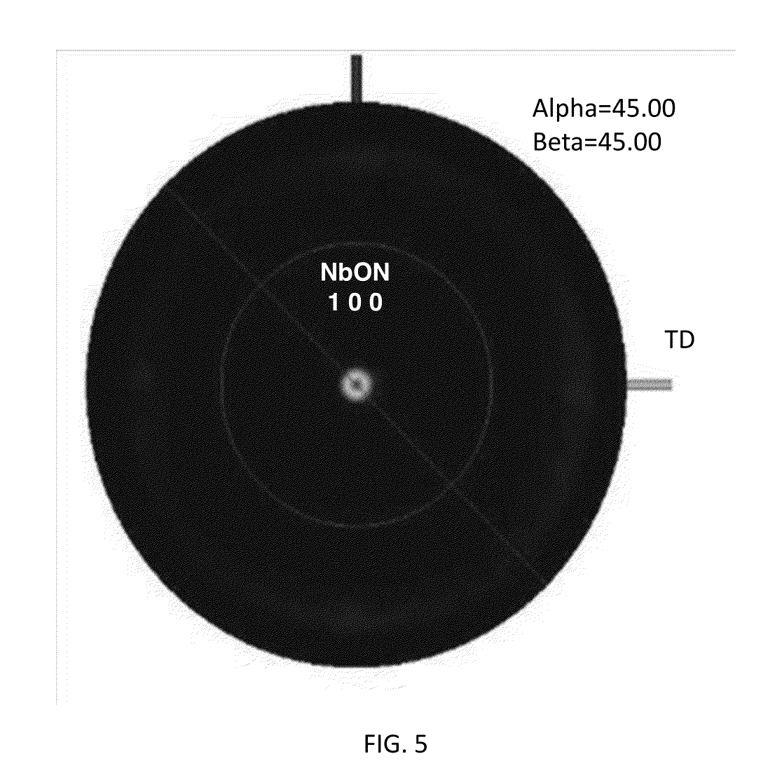

FIG. 5 shows a pole measurement result of the single-crystalline NbON film 120 having a (100) plane orientation in the inventive example 1. As shown in FIG. 5; the (100) plane of the single-crystalline NbON film 120 was observed as only one point at the center thereof. This means that the single-crystalline NbON film 120 is oriented completely in a (100) plane.

FIG. 6 shows a cross-sectional SEM image of the semiconductor photoelectrode 100 according to the inventive example 1. The single-crystalline NbON film 120 has neither an interspace nor a pinhole. The single-crystalline NbON film 120 is flat and dense.

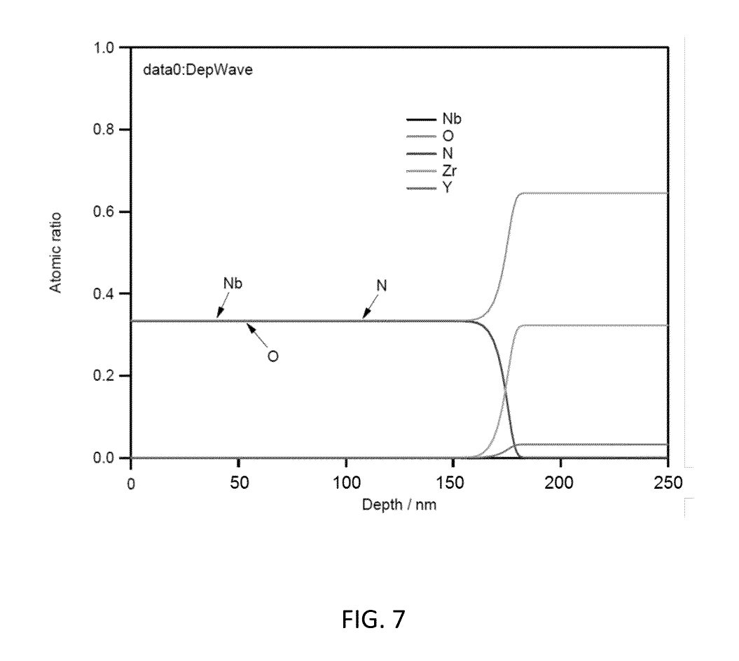

FIG. 7 shows a result of the composition analysis of the semiconductor photoelectrode 100 along the depth direction thereof by a Rutherford back scattering (hereinafter, referred to as “RBS”) analysis method. As is clear from FIG. 7, the Nb:O:N ratio (atomic ratio) is substantially equal to 1:1:1 in the single-crystalline NbON film 120. This suggests that the single-crystalline NbON film 120 formed in the inventive example 1 has few point defects such as vacancies, interstitial atoms, and antisite defects, which cause the recombination of an electron and a hole.

### Inventive Example 2

In the inventive example 2, the semiconductor photoelectrode 100 shown in FIG. 1 was fabricated. First, a titanium oxide substrate 110 having a (101) plane orientation (available from Shinkosha Co., Ltd.) was prepared. This titanium oxide substrate had a rutile structure. While the titanium oxide substrate 110 was heated to 650 degrees Celsius, a single-crystalline NbON film 120 having a thickness of 150 nanometers was formed on the titanium oxide substrate 110 by a reactive sputtering method under a mixed atmosphere of oxygen and nitrogen (O₂:N₂=1:20, volume ratio). The sputtering target was formed of niobium nitride represented by the chemical formula NbN.

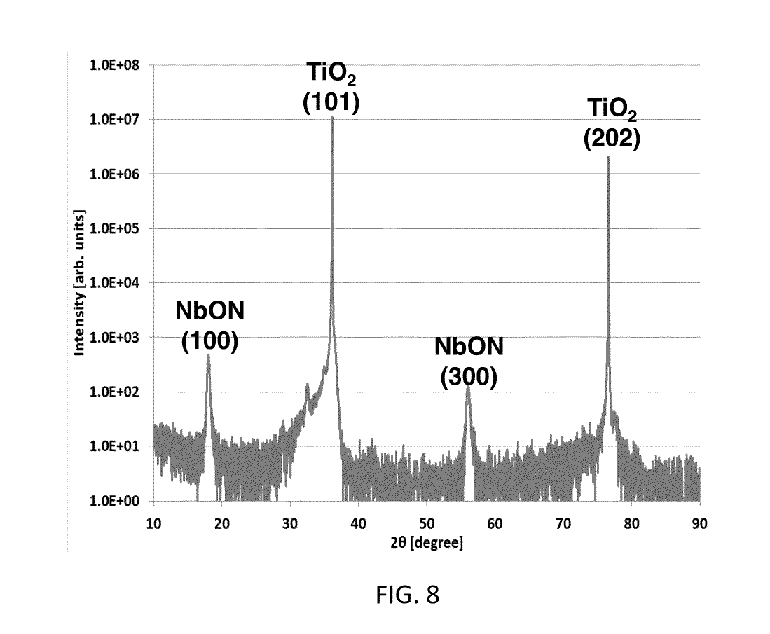

Similarly to the case of the inventive example 1, the thus-formed single-crystalline NbON film 120 was subjected to the X-ray diffraction measurement analysis according to a 2θ-ω scan method. FIG. 8 shows a result of the 2θ-ω scan measurement in the inventive example 2. As shown in FIG. 8, observed was four peaks of a (101) plane derived from titanium oxide, a (202) plane derived from titanium oxide, a (100) plane derived from NbON, and a (300) plane derived from NbON. As just described, except for the two peaks derived from the titanium oxide substrate, only the peaks of (h00) planes derived from NbON were observed. In this way, a single-crystalline NbON film 120 having a (100) plane orientation was epitaxially grown on the titanium oxide substrate 110 having a (100) plane orientation.

### Inventive Example 3

In the inventive example 3, the semiconductor photoelectrode 100 shown in FIG. 1 was fabricated. First, a yttrium-aluminum complex oxide substrate 110 having a (001) plane orientation (available from SurfaceNet GMBH) was prepared. The substrate was formed of a yttrium-aluminum complex oxide represented by the chemical formula YAlO₃. While the yttrium-aluminum complex oxide substrate 110 was heated to 650 degrees Celsius, a single-crystalline NbON film 120 having a thickness of 150 nanometers was formed on the yttrium-aluminum complex oxide substrate 110 by a reactive sputtering method under a mixed atmosphere of oxygen and nitrogen (O₂:N₂=1:20, volume ratio). The sputtering target was formed of niobium nitride represented by the chemical formula NbN.

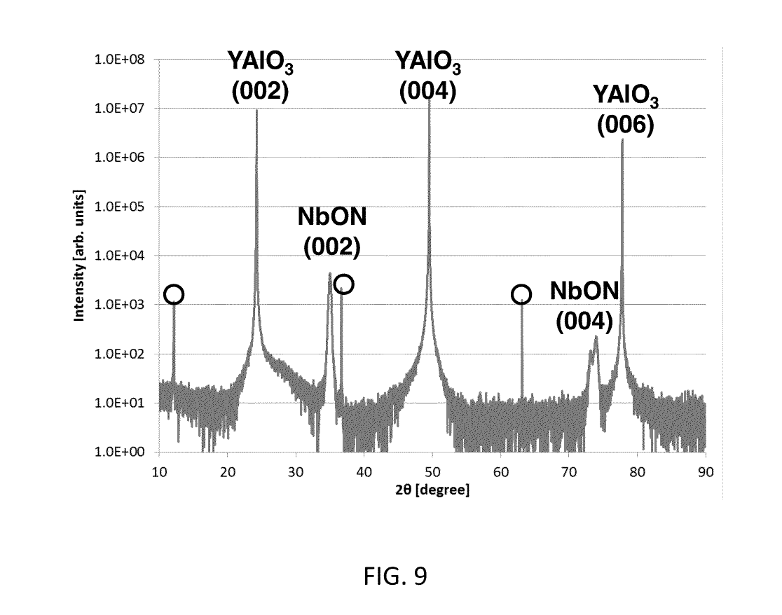

Similarly to the case of the inventive example 1, the thus-formed single-crystalline NbON film 120 was subjected to the X-ray diffraction measurement analysis according to a 2θ-ω scan method. FIG. 9 shows a result of the 2θ-ω scan measurement in the inventive example 3. As shown in FIG. 9, observed was five peaks of a (002) plane derived from YAlO₃, a (004) plane derived from YAlO₃, a (006) plane derived from YAlO₃, a (002) plane derived from NbON, and a (004) plane derived from NbON. As just described, except for the two peaks derived from the yttrium-aluminum complex oxide substrate 110, only the peaks of (001) (where l is a lower-case letter of “L” and is a natural number) planes derived from NbON were observed. In this way, a single-crystalline NbON film 120 having a (001) plane orientation was epitaxially grown on the yttrium-aluminum complex oxide substrate 110 having a (001) plane orientation. In FIG. 9, three peaks indicated by the white circles are derived from the impurities included in the YAlO₃ substrate, the present inventors believe.

### Comparative Example 1a

In the comparative example 1a, the semiconductor photoelectrode 100 shown in FIG. 1 was fabricated. First, a quartz substrate 110 (available from EIKOH Co., Ltd.) was prepared. While the quartz substrate 110 was heated to 760 degrees Celsius, a NbON film having a thickness of 90 nanometers was formed on the quartz substrate 110 by a reactive sputtering method under a mixed atmosphere of oxygen and nitrogen (O₂:N₂=1:20, volume ratio). The sputtering target was formed of niobium nitride represented by the chemical formula NbN.

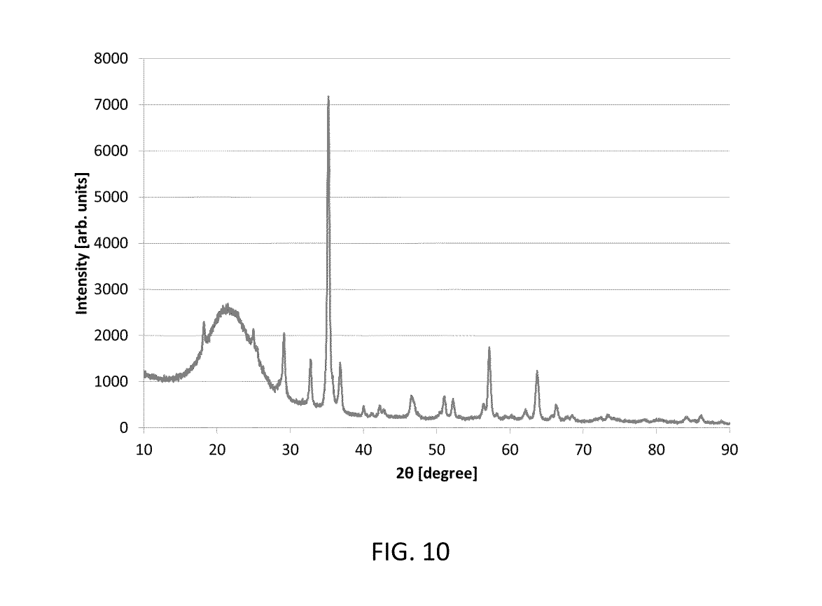

The thus-formed NbON film was subjected to a grazing-incidence X-ray diffraction measurement analysis. The incidence angle was set to 0.5 degrees. FIG. 10 shows a result of the grazing-incidence X-ray diffraction measurement analysis. All the detected peaks are derived from NbON. Therefore, the formed NbON film was a single-phase NbON film. As shown in FIG. 10, a variety of peaks derived from NbON were observed. For this reason, the NbON film according to the comparative example 1a was a non-oriented polycrystalline film.

FIG. 11 shows a cross-sectional SEM image of the semiconductor photoelectrode 100 according to the comparative example 1a. The NbON film was dense, however, the surface of the NbON film was rougher than the surface of the NbON film according to the inventive example 1.

### Comparative Example 1b)

In the comparative example 1b, the semiconductor photoelectrode 100 shown in FIG. 1 was fabricated. First, a quartz substrate 110 was prepared. While the quartz substrate 110 was heated to 650 degrees Celsius, a NbON film having a thickness of 300 nanometers was formed on the quartz substrate 110 by a reactive sputtering method under a mixed atmosphere of oxygen and nitrogen (O₂:N₂=1:20, volume ratio). The sputtering target was formed of niobium nitride represented by the chemical formula NbN.

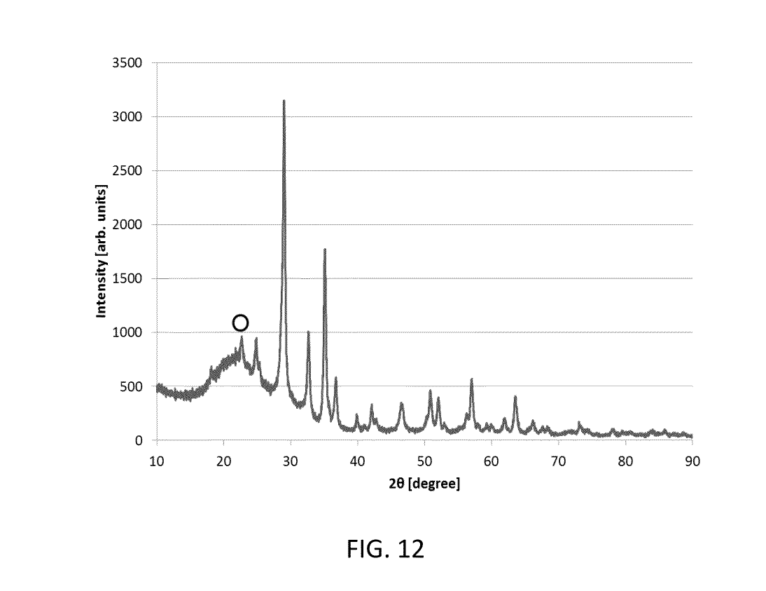

The thus-formed NbON film was subjected to a grazing-incidence X-ray diffraction measurement analysis. The incidence angle was set to 0.5 degrees. FIG. 12 shows a result of the grazing-incidence X-ray diffraction measurement analysis. The peak indicated by the circle is derived from Nb₂O₅. Except for the peak from Nb₂O₅, all of the detected peaks are derived from NbON. For this reason, the formed NbON film was not a single-phase NbON film. The formed NbON film contained a small amount of Nb₂O₅ as impurities. Furthermore, as shown in FIG. 12, a variety of peaks derived from NbON were observed. For this reason, the NbON film according to the comparative example 1b was a non-oriented polycrystalline film.

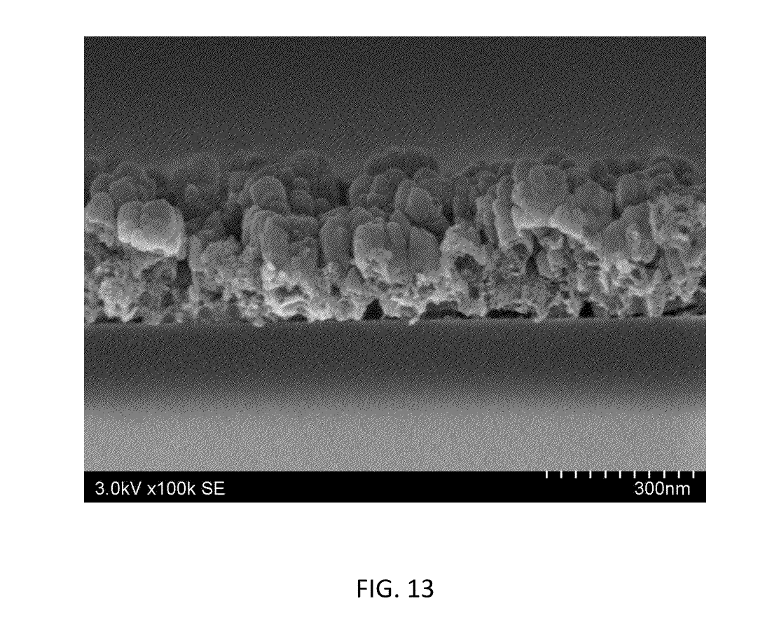

FIG. 13 shows a cross-sectional SEM image of the semiconductor photoelectrode 100 according to the comparative example 1b. The NbON film had a lot of interspaces. Furthermore, the surface of the NbON film was significantly rough.

### Comparative Example 2

In the comparative example 2, the semiconductor photoelectrode 100 shown in FIG. 1 was fabricated. First, a FTO/quartz substrate 110 was prepared. The FTO/quarts substrate had a quartz substrate and a film formed of fluorine-doped SnO₂ (hereinafter, referred to as “FTO”) formed thereon. While the FTO/quartz substrate 110 was heated to 760 degrees Celsius, a NbON film having a thickness of 90 nanometers was formed on the FTO/quartz substrate 110 by a reactive sputtering method under a mixed atmosphere of oxygen and nitrogen (O₂:N₂=1:20, volume ratio). The sputtering target was formed of niobium nitride represented by the chemical formula NbN.

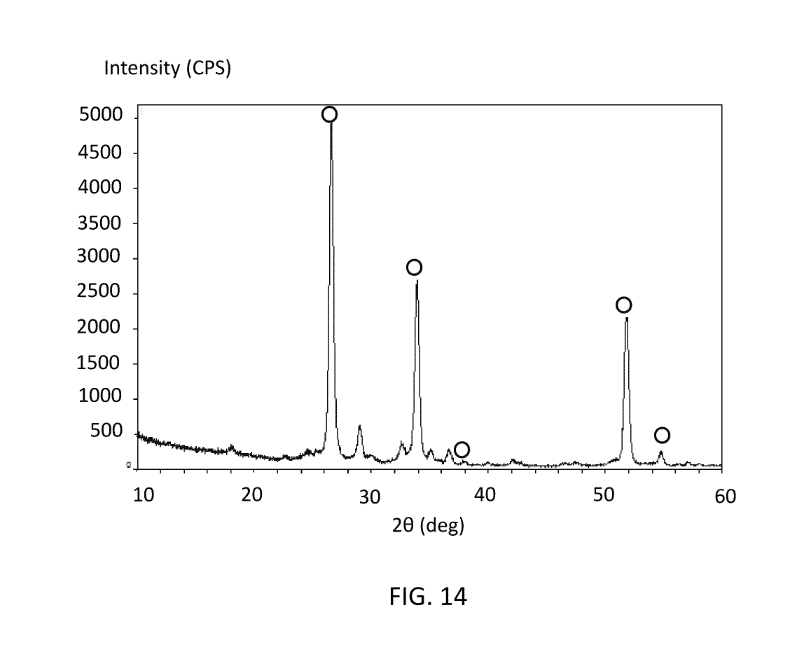

The thus-formed NbON film was subjected to a grazing-incidence X-ray diffraction measurement analysis. The incidence angle was set to 0.5 degrees. FIG. 14 shows a result of the grazing-incidence X-ray diffraction measurement analysis. The peaks indicated by the circles are derived from SnO₂ contained in the substrate 110. Except for the peaks from SnO₂, all of the detected peaks are derived from NbON. For this reason, the formed NbON film was a single-phase NbON film. Furthermore, as shown in FIG. 14, a variety of peaks derived from NbON were observed. For this reason, the NbON film according to the comparative example 2 was a non-oriented polycrystalline film.

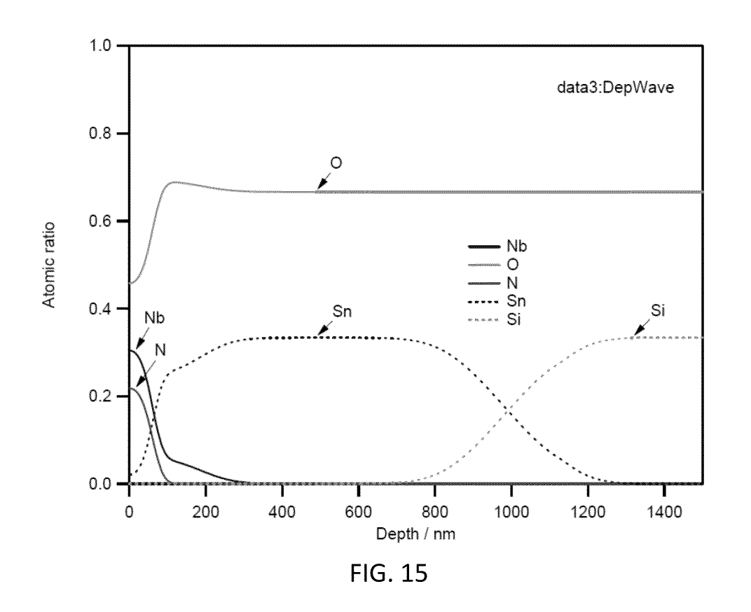

FIG. 15 shows a result of the composition analysis of the semiconductor photoelectrode 100 along the depth direction thereof by a RBS analysis method in the comparative example 2. In FIG. 15, the NbON film corresponds to the interval of the depth between 0 nanometers and 90 nanometers. As is clear from FIG. 15, the Nb:O:N ratio (atomic ratio) of the NbON film formed in the comparative example 2 deviates from the ratio of 1:1:1. This suggests that the NbON film formed in the comparative example 2 may have point defects such as vacancies, interstitial atoms, and antisite defects, which cause the recombination of an electron and a hole.

As demonstrated in the inventive examples 1-3, a single-crystalline NbON film 120 having a Nb:O:N ratio of 1:1:1 is formed by epitaxially growing the NbON film on one substrate 110 selected from the group consisting of a YSZ substrate, a TiO₂ substrate, and a yttrium-aluminum complex oxide substrate.

### INDUSTRIAL APPLICABILITY

The single-crystalline NbON film according to the present invention can be used for a hydrogen generation device.

### REFERENCE SIGNS LIST

100 semiconductor photoelectrode
110 substrate
111 ohmic electrode
120 single-crystalline NbON film
600 hydrogen generation device
610 container
620 semiconductor photoelectrode
621 electric conductor
622 NbON film
630 counter electrode
640 liquid
650 conducting wire

1. A method for fabricating a single-crystalline niobium oxynitride film formed of a niobium oxynitride represented by the chemical formula NbON, the method comprising:
(a) epitaxially growing the single-crystalline niobium oxynitride film on one substrate selected from the group consisting of a yttria-stabilized zirconia substrate, a titanium oxide substrate, and a yttrium-aluminum complex oxide substrate.

2. The method according to claim 1, wherein
the one substrate is a yttria-stabilized zirconia substrate; and
the yttria-stabilized zirconia substrate is oriented in a [100] direction.

3. The method according to claim 1, wherein
the one substrate is a titanium oxide substrate; and
the titanium oxide substrate is oriented in a [101] direction.

4. The method according to claim 1, wherein
the one substrate is a yttrium-aluminum complex oxide substrate; and the yttrium-aluminum complex oxide substrate is oriented in a [001] direction.

5. The method according to claim 1, wherein
a sputtering method is used in the step (a).

6. The method according to claim 5, wherein
a sputtering target formed of niobium nitride represented by the chemical formula NbN is used in the step (a); and
the single-crystalline niobium oxynitride film is epitaxially grown under a mixed atmosphere of oxygen and nitrogen.

7. A method for fabricating a semiconductor photoelectrode, the method comprising:
(a) epitaxially growing a single-crystalline niobium oxynitride film on a front surface of a titanium oxide substrate; and
(b) imparting electrical conductivity to the titanium oxide substrate by doping the titanium oxide substrate with niobium from a back surface of the titanium oxide substrate to provide the semiconductor photoelectrode comprising the titanium oxide substrate and the single-crystalline niobium oxynitride film.

8. The method according to claim 7, wherein
the titanium oxide substrate is oriented in a [101] direction.

9. The method according to claim 7, wherein
a sputtering method is used in the step (a).

10. The method according to claim 7, wherein
a sputtering target formed of niobium nitride represented by the chemical formula NbN is used in the step (a); and
the single-crystalline niobium oxynitride film is epitaxially grown under a mixed atmosphere of oxygen and nitrogen.

11. A method for fabricating a semiconductor photoelectrode, the method comprising:
(a) reducing a surface of a yttria-stabilized zirconia substrate having crystallinity by annealing the surface of the yttria-stabilized zirconia substrate in a vacuum to provide a conductive film on the surface of the yttria-stabilized zirconia substrate, wherein
the crystallinity of the yttria-stabilized zirconia substrate is maintained at a surface of the conductive film, and
(b) epitaxially growing a single-crystalline niobium oxynitride film on the conductive film to provide the semiconductor photoelectrode comprising the yttria-stabilized zirconia substrate, the conductive film, and the single-crystalline niobium oxynitride film.

12. The method according to claim 11, wherein
the yttria-stabilized zirconia substrate is oriented in a [100] direction.

13. The method according to claim 11, wherein
a sputtering method is used in the step (b).

14. The method according to claim 13, wherein
a sputtering target formed of niobium nitride represented by the chemical formula NbN is used in the step (b); and
the single-crystalline niobium oxynitride film is epitaxially grown under a mixed atmosphere of oxygen and nitrogen.

15. A single-crystalline niobium oxynitride film formed of a niobium oxynitride represented by the chemical formula NbON.

16. A semiconductor photoelectrode comprising a single-crystalline niobium oxynitride formed of a niobium oxynitride represented by the chemical formula NbON.

17. A semiconductor photoelectrode for generating hydrogen, the semiconductor photoelectrode comprising a single-crystalline niobium oxynitride formed of a niobium oxynitride represented by the chemical formula NbON.

18. A hydrogen generation device, comprising:
a semiconductor photoelectrode comprising, on a surface thereof, a single-crystalline niobium oxynitride formed of a niobium oxynitride represented by the chemical formula NbON;
a counter electrode electrically connected to the semiconductor photoelectrode;
a liquid in contact with the single-crystalline niobium oxynitride and the counter electrode; and
a container containing the semiconductor photoelectrode, the counter electrode, and the liquid, wherein
the liquid is water or an electrolyte aqueous solution; and
hydrogen is generated on a surface of the counter electrode by irradiating the single-crystalline niobium oxynitride with light.

19. A method for generating hydrogen, comprising:
(a) preparing a hydrogen generation device, comprising:
a semiconductor photoelectrode comprising a single-crystalline niobium oxynitride formed of a niobium oxynitride represented by the chemical formula NbON;
a counter electrode electrically connected to the semiconductor photoelectrode;
a liquid in contact with the single-crystalline niobium oxynitride and the counter electrode; and
a container containing the semiconductor photoelectrode, the counter electrode, and the liquid, wherein
the liquid is water or an electrolyte aqueous solution; and
(b) irradiating the single-crystalline niobium oxynitride with light to generate hydrogen on a surface of the counter electrode.
